(19) United States
(12) Patent Application Publication
(10) Pub. No.: US 2013/0207143 A1
(43) Pub. Date: Aug. 15, 2013

(54) PATTERNED SUBSTRATE OF LIGHT EMITTING SEMICONDUCTOR DEVICE AND MANUFACTURING METHOD THEREOF

(71) Applicants: Hsiu-Mei Chou, Hsinchu City (TW); Jun-Rong Chen, Taichung City (TW)

(72) Inventors: Hsiu-Mei Chou, Hsinchu City (TW); Jun-Rong Chen, Taichung City (TW)

(73) Assignee: LEXTAR ELECTRONICS CORPORATION, Hsinchu (TW)

(21) Appl. No.: 13/548,459

(22) Filed: Jul. 13, 2012

(30) Foreign Application Priority Data
Feb. 14, 2012 (TW) 101104751

(51) Int. Cl. H01L 33/58; H01L 33/00

(52) U.S. Cl. 257/98; 257/79; 438/22; 257/E33.074; 257/E33.001

(57) ABSTRACT

A patterned substrate of a light emitting semiconductor device has a plurality of convex members on a top surface thereof. Each convex member has a substantially flat top surface and a plurality of convex arc-shaped sidewalls.

### RELATED APPLICATIONS

This application claims priority to Taiwan Application Serial Number 101104751, filed Feb. 14, 2012, which is herein incorporated by reference.

### BACKGROUND

1. Field of Invention

The present invention relates to light emitting diode technology. More particularly, the present invention relates to a patterned substrate of a light emitting diode device and a manufacturing method thereof.

2. Description of Related Art

Light-emitting diodes (LEDs) are becoming increasingly important and are being used in more and more applications due their low power consumption and long life. LEDs are generally expected to replace traditional fluorescent illumination devices. Whether LEDs can be broadly implemented in a variety of lighting apparatuses or not depends on their light-emitting efficiency and cost. Increasing the light-extraction efficiency of LEDs is key to improving the light-emitting efficiency thereof.

Surface roughening, which is performed on a substrate or on a top semiconductor layer, has been an effective means to enhance the light-extraction efficiency of LEDs. Another effective way involves the use of a “patterned sapphire substrate,” which scatters light emitted from a light-emitting layer so as to enhance the light-extraction efficiency of an LED. While there are various conventional ways in which to pattern a sapphire substrate, the light-extraction efficiency obtained with the use of sapphire substrates patterned using such conventional techniques is still in need of improvement.

### SUMMARY

The present invention provides an improved patterned substrate of a light emitting semiconductor device and a manufacturing method thereof.

In accordance with the foregoing and other objectives of the present invention, a patterned substrate of a light emitting semiconductor device has a plurality of convex members on a top surface thereof. Each convex member has a substantially flat top surface and a plurality of convex arc-shaped sidewalls.

According to another embodiment disclosed herein, an edge number of a top surface of each convex member is equal to or less than a sidewall number of the convex arc-shaped sidewalls of each convex member.

According to another embodiment disclosed herein, an edge number of a top surface of each convex member is equal to or less than an edge number of a horizontal cross-section of each convex member, and the horizontal cross-section is parallel with the substantially flat top surface.

According to another embodiment disclosed herein, the patterned substrate is a sapphire substrate or a silicon-based substrate.

In accordance with the foregoing and other objectives of the present invention, a light emitting semiconductor device includes a patterned substrate, a first type semiconductor layer, a light-emitting layer and a second type semiconductor layer. The patterned substrate has a plurality of convex members on a top thereof and each convex member has a substantially flat top surface and a plurality of convex arc-shaped sidewalls. The first type semiconductor layer is located on the patterned substrate. The light-emitting layer is located on the first type semiconductor layer. The second type semiconductor layer is located on the light-emitting layer.

According to another embodiment disclosed herein, an edge number of a top surface of each convex member is equal to or less than a sidewall number of the convex arc-shaped sidewalls of each convex member.

According to another embodiment disclosed herein, an edge number of a top surface of each convex member is equal to or less than an edge number of a horizontal cross-section of each convex member, and the horizontal cross-section is parallel with the substantially flat top surface.

According to another embodiment disclosed herein, the patterned substrate is a sapphire substrate or a silicon-based substrate.

According to another embodiment disclosed herein, the first type semiconductor layer is an n-type semiconductor layer while the second type semiconductor layer is a p-type semiconductor layer, or the first type semiconductor layer is a p-type semiconductor layer while the second type semiconductor layer is an n-type semiconductor layer.

In accordance with the foregoing and other objectives of the present invention, a method for manufacturing a patterned substrate of light emitting semiconductor device includes the steps of providing a substrate, forming an etching stop layer on the substrate, forming a photoresist layer on the etching stop layer; using a nano/micron meter imprinting process or a photolithography process to pattern the photoresist layer to form a plurality of polygons, dry etching the substrate and the etching stop layer using the patterned photoresist layer as a mask so as to form a plurality of polygonal convex members on a top of the substrate, removing the photoresist layer and the etching stop layer from a top surface of each polygonal convex member, and wet etching sidewalls of each polygonal convex member so as to form a plurality of convex arc-shaped sidewalls.

According to another embodiment disclosed herein, the dry etching is performed using a plasma etching process that employs radio frequency energy to create a plasma of ionized atoms and radicals of reactive gases capable of etching various semiconductors.

According to another embodiment disclosed herein, an etchant of the wet etching is a mixed acid solution.

According to another embodiment disclosed herein, the etching stop layer is made from a material selected from the group consisting of silicon dioxide and silicon nitride.

According to another embodiment disclosed herein, an edge number of a top surface of each convex member is equal to or less than a sidewall number of the convex arc-shaped sidewalls of each convex member.

According to another embodiment disclosed herein, an edge number of a top surface of each convex member is equal to or less than an edge number of a horizontal cross-section of each convex member, and the horizontal cross-section is parallel with the substantially flat top surface.

According to another embodiment disclosed herein, the patterned substrate is a sapphire substrate or a silicon-based substrate.

Thus, the patterned substrate of a light emitting semiconductor device of this disclosure has the convex members equipped with multiple convex arc-shaped sidewalls to generate more scattering or diffracting light and therefore achieves a higher light extraction rate for the light emitting semiconductor device. Through such a configuration, both top-emitting light power and side-emitting light power are enhanced. Similar advantages are realized with the method for manufacturing a patterned substrate of a light emitting semiconductor device of this disclosure.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a cross-sectional view of a light emitting semiconductor device according to an embodiment of this invention;

FIG. 2A illustrates a top view of a convex member on a patterned substrate according to an embodiment of this invention;

FIG. 2B illustrates a perspective view of the convex member in FIG. 2A;

FIG. 3 illustrates a top view of a convex member on a patterned substrate according to another embodiment of this invention;

FIG. 4 illustrates a horizontal cross-section of the convex member in FIG. 2B or FIG. 3;

FIG. 5 illustrates schematic cross-sectional views of sequential steps involved in manufacturing a patterned substrate of a light emitting semiconductor device according to an embodiment of this invention;

FIG. 5A illustrates an enlarged view of a portion of a photomask that may be used in the sequential steps depicted in FIG. 5;

FIG. 6 illustrates schematic cross-sectional views of sequential steps involved in manufacturing a patterned substrate of a light emitting semiconductor device according to another embodiment of this invention;

FIG. 6A illustrates an enlarged view of a portion of a nano/micron meter imprint mask that may be used in the sequential steps depicted in FIG. 6;

FIG. 6B illustrates an enlarged view of a portion of another nano/micron meter imprint mask that may be used in the sequential steps depicted in FIG. 6; and

FIG. 7 illustrates optical experimental results for a light emitting semiconductor device according to an embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

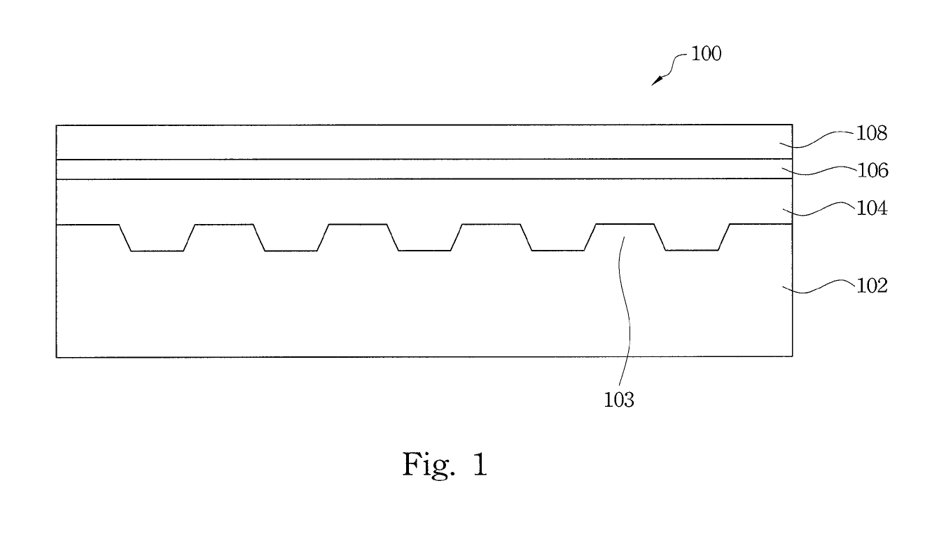

FIG. 1 illustrates a cross-sectional view of a light emitting semiconductor device according to an embodiment of this invention. A light emitting semiconductor device 100 includes a patterned substrate 102, a first type semiconductor layer 104, a light-emitting layer 106 and a second type semiconductor layer 108. The patterned substrate 102 has a plurality of convex members 103 on a top surface thereof in order to increase a light extraction rate of the light emitting semiconductor device. In this embodiment, the first type semiconductor layer 104 is an n-type semiconductor layer while the second type semiconductor layer 108 is a p-type semiconductor layer, or the first type semiconductor layer 104 is a p-type semiconductor layer while the second type semiconductor layer 108 is an n-type semiconductor layer. In this embodiment, the patterned substrate 102 can be a sapphire substrate or a silicon-based substrate, but is not limited to these materials. The details of the convex members 103 are described below.

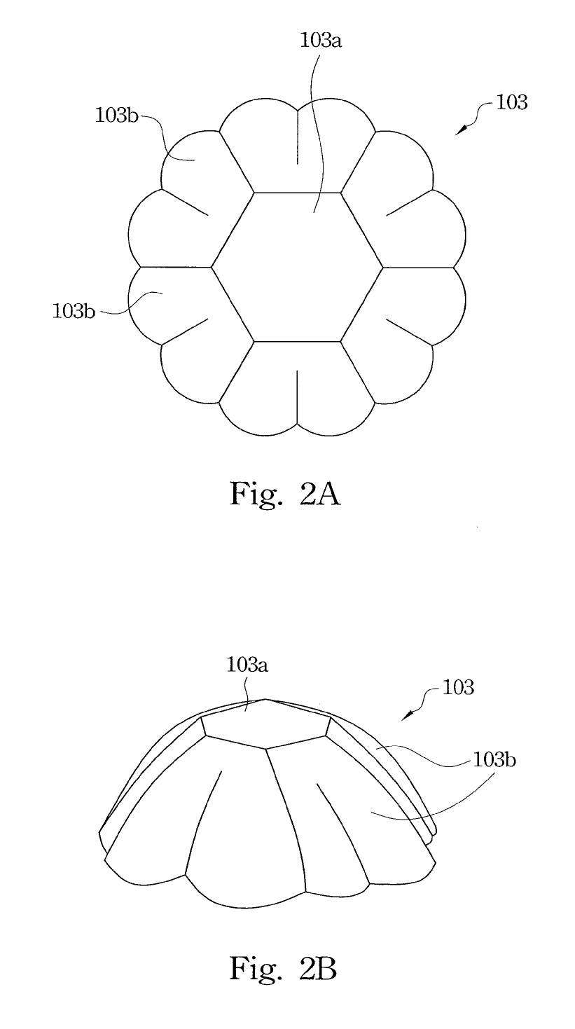

FIG. 2A illustrates a top view of a convex member on a patterned substrate according to an embodiment of this invention, and FIG. 2B illustrates a perspective view of the convex member in FIG. 2A. The convex member 103 is basically a pudding-like or pyramid-like convex member, which has a substantially flat top surface 103a and a plurality of convex arc-shaped sidewalls 103b. In this embodiment, the top surface 103a of each convex member 103 has a number of edges (hereinafter referred to as an “edge number”) that is less than a number of sidewalls (hereinafter referred to as a “sidewall number”) of the convex arc-shaped sidewalls 103b of each convex member 103.

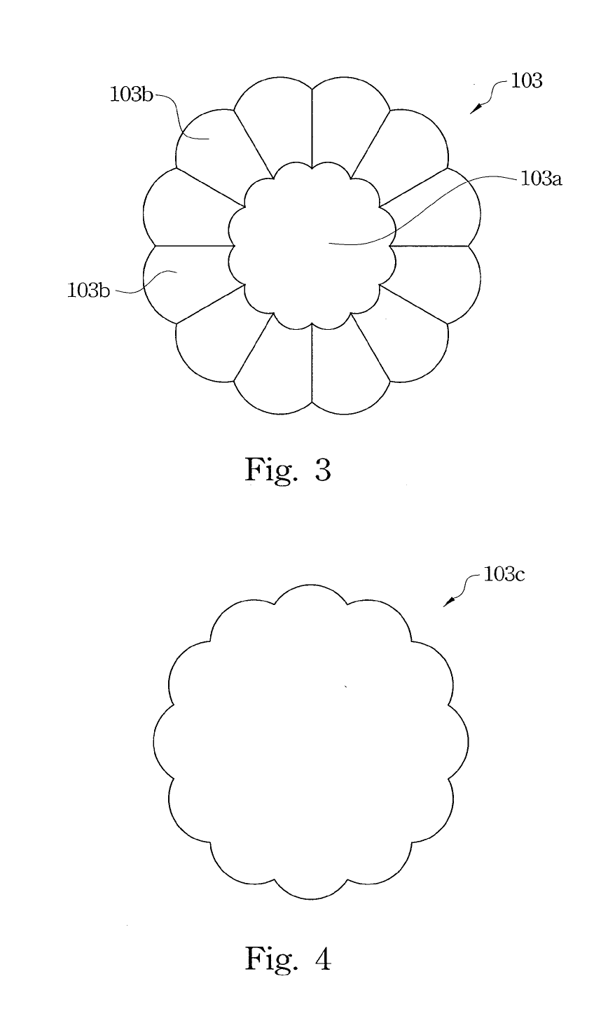

FIG. 3 illustrates a top view of a convex member on a patterned substrate according to another embodiment of this invention. The convex member of FIG. 3 is different from the convex member of FIG. 2A or FIG. 2B in that an edge number of a top surface 103a of the convex member 103 of FIG. 3 is equal to a sidewall number of the convex arc-shaped sidewalls 103b of the convex member 103, while the edge number of the top surface 103a of the convex member 103 of FIG. 2A or FIG. 2B is less than the sidewall number of the convex arc-shaped sidewalls 103b of the convex member 103.

According to experimental results, the light emitting semiconductor device has a higher light extraction rate with the convex members 103 equipped with the convex arc-shaped sidewalls 103b of this disclosure than it does with conventional convex members equipped with flat sidewalls. The table below shows the experimental results. In the table, “hexagonal pyramid with flat sidewalls” indicates the conventional convex members, while “pyramid with multiple convex arc-shaped sidewalls” indicates the convex members of this disclosure as illustrated in FIG. 2A and FIG. 2B. The light emitting semiconductor device has a higher emitting power when its convex members are “pyramid with multiple convex arc-shaped sidewalls” than when its convex members are “hexagonal pyramid with flat sidewalls.” The emitting power is enhanced because the “convex arc-shaped sidewalls” have a larger surface area than do “flat sidewalls.” Hence, the reflective angles are changed due to the convex arc-shaped sidewalls so as to increase the top-emitting power.

| Shape of | Test of chip on wafer | | | | | |
|---|---|---|---|---|---|---|
| convex members | Iv (mW/Sr) | λp (nm) | Vf1 (1uA) | Vf2 (20 mA) | Ir (−5 V) | Vr (−10 uA) |
| Hexagonal pyramid with | 85.3 | 446.4 | 2.2 | 3.1 | 0.024 | 26.89 |
| flat sidewalls | | | | | | |
| Pyramid with multiple | 108.3 | 447.6 | 2.2 | 3.1 | 0.023 | 26.46 |
| convex arc-shaped | | | | | | |
| sidewalls | | | | | | |

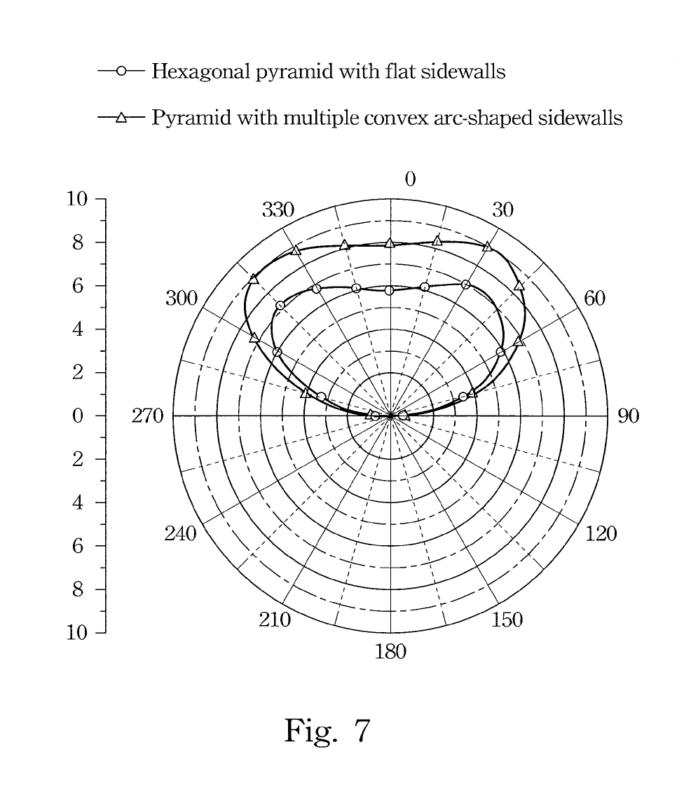

FIG. 7 illustrates optical experimental results for a light emitting semiconductor device according to an embodiment of this invention. This diagram provides comparison results between the conventional convex members with “hexagonal pyramid with flat sidewalls” and the convex members with “pyramid with multiple convex arc-shaped sidewalls” of this disclosure. When the convex members on the sapphire substrate have convex arc-shaped sidewalls, its side-emitting power enhances due to the increase in surface area and its side extraction rate is better compared with the convex members with flat sidewalls.

FIG. 4 illustrates a horizontal cross-section of the convex member in FIG. 2B or FIG. 3. The horizontal cross-section 103c is taken along a plane that is parallel with the top surface 103a of the convex member 103 in FIG. 2B or FIG. 3. With additional reference to FIG. 2A and FIG. 3, comparing the top surface 103a with the horizontal cross-section 103c, an edge number of the top surface 103a of the convex member 103 is equal to or less than an edge number of the horizontal cross-section 103c of the convex member 103. Details related to forming the convex members 103 of this disclosure are described below.

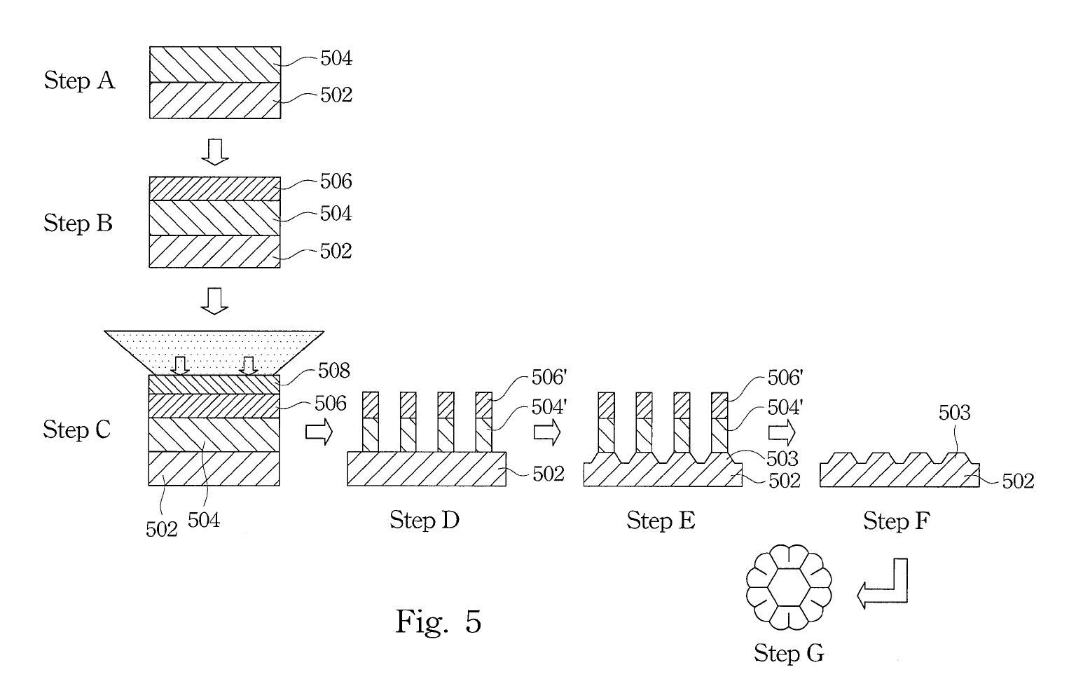

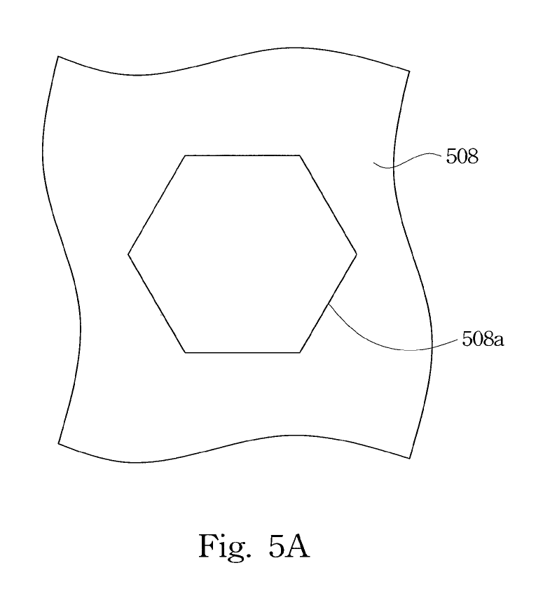

FIG. 5 illustrates schematic cross-sectional views of sequential steps involved in manufacturing a patterned substrate of a light emitting semiconductor device according to an embodiment of this invention. Each cross-sectional view illustrated corresponds to one step.

In step A, a substrate 502 is provided and an etching stop layer 504 is formed on the substrate 502. In this embodiment, the substrate 502 can be a sapphire substrate or a silicon-based substrate, but is not limited to these materials. The etching stop layer 504 can be silicon dioxide or silicon nitride, but is not limited to these materials.

In step B, a photoresist layer 506 is formed on the etching stop layer 504. The photoresist layer 506 can be any photoresist material used in photolithography processes.

In step C, a photolithography process is used to pattern the photoresist layer 506, i.e., a photomask 508 is used to execute the photolithography process upon the photoresist layer 506 to form multiple uniformly organized polygons thereon. In this embodiment, the photomask 508 may be formed with hexagons 508a, as shown in FIG. 5A, to form the polygons on the photoresist layer 506.

In step D, the patterned photoresist layer 506′ is used as a mask to dry etch the etching stop layer 504 to form a patterned etching stop layer 504′. In this embodiment, the dry etch process can be a plasma etching process that employs radio frequency energy (RF) to create a plasma of ionized atoms and radicals of reactive gases capable of etching various semiconductors.

In step E, the patterned photoresist layer 506′ is used as a mask to further dry etch the substrate 502. In this step, the patterned etching stop layer 504′ also serves as an “etching mask”, i.e., the patterned etching stop layer 504′ performs the same function as the patterned photoresist layer 506′. Therefore, the mask is thickened by adding the patterned etching stop layer 504′. When the patterned photoresist layer 506′ is worn in the dry etch process, the patterned etching stop layer 504′ serves as a backup mask. In this embodiment, the dry etch process can also be a plasma etching process that employs radio frequency energy (RF) to create a plasma of ionized atoms and radicals of reactive gases capable of etching various semiconductors. After the dry etch step, the convex members 503 can be formed on the top surface of the substrate 502 with a trapezoid-like cross-section.

Step D and step E can be executed sequentially or separately as required.

In step F, the patterned photoresist layer 506′ and the patterned etching stop layer 504′ are removed from the top surface of the polygonal convex members 503 so as to expose a top surface of the substrate 502.

In step G, multiple sidewalls of each polygonal convex member 503 are wet etched so as to form a plurality of convex arc-shaped sidewalls, as in the case of the convex member 103 illustrated in FIG. 2A and FIG. 2B. In this embodiment, the etchant used for wet etching the sapphire substrate or the silicon-based substrate can be a heated mixed acid solution, e.g., a mixed solution of phosphoric acid and sulfuric acid, but is not limited to these acids. After wet etching the sidewalls of the polygonal convex members 503, a sidewall number of the convex arc-shaped sidewalls of each convex member is greater than an edge number of a top surface of each convex member, as in the case of the convex member 103 illustrated in FIG. 2A and FIG. 2B. When a sapphire substrate is used as the patterned substrate for the light emitting semiconductor device, the wet etching process can be performed along R-planes of the sapphire substrate to increase the convex arc-shaped sidewalls.

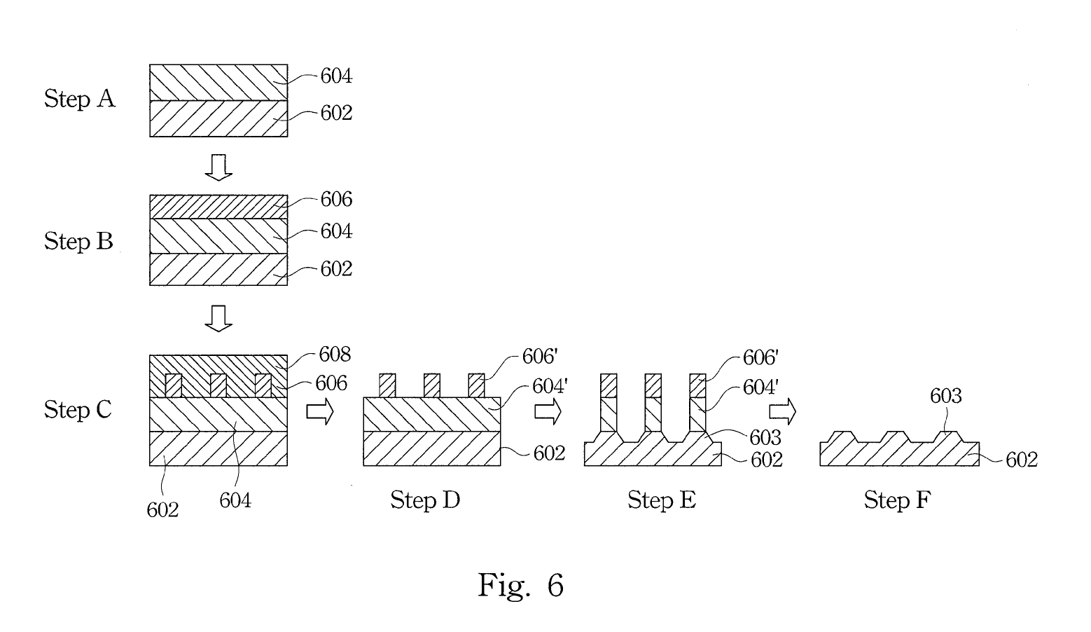

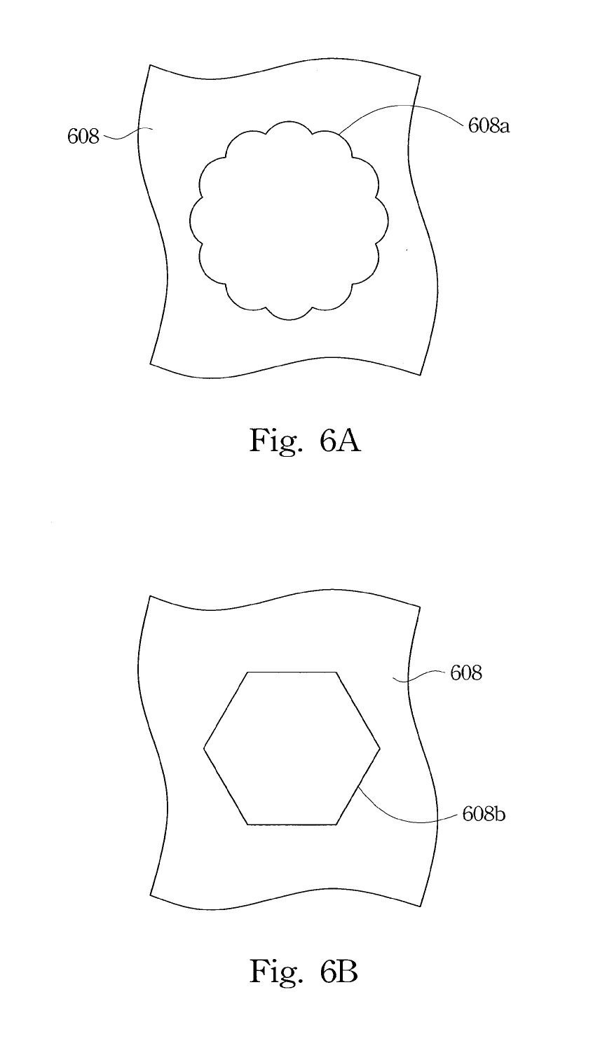

FIG. 6 illustrates schematic cross-sectional views of sequential steps involved in manufacturing a patterned substrate of a light emitting semiconductor device according to another embodiment of this invention. Each cross-sectional view illustrated corresponds to one step. The embodiment of FIG. 6 is different from the embodiment of FIG. 5 in that a nano/micron meter imprint mask 608 (see FIG. 6A and 6B) is used to pattern the photoresist layer rather than a photolithography process.

In step A, a substrate 602 is provided and an etching stop layer 604 is formed on the substrate 602. In this embodiment, the substrate 602 can be a sapphire substrate or a silicon-based substrate, but is not limited to these materials. The etching stop layer 604 can be silicon dioxide or silicon nitride, but is not limited to these materials.

In step B, a photoresist layer 606 is formed on the etching stop layer 604. The photoresist layer 606 can be any photoresist material used in nano/micron meter imprinting processes.

In step C, a nano/micron meter imprinting process is used to pattern the photoresist layer 606, i.e., a nano/micron meter imprint mask 608 is used to execute the imprinting process upon the photoresist layer 606 to form multiple uniformly organized polygons thereon. In this embodiment, the nano/micron meter imprint mask 608 can be formed with imprint patterns 608a each in a polygonal shape, as illustrated in FIG. 6A, to form the polygons on the photoresist layer 606, or with imprint patterns 608b each in a polygonal shape, as illustrated in FIG. 6B, to form the polygons on the photoresist layer 606.

In step D, the nano/micron meter imprint mask 608 is removed to expose the patterned photoresist layer 606′.

In step E, the patterned photoresist layer 606′ is used as a mask to dry etch the etching stop layer 604 and the substrate 602 to form a patterned etching stop layer 604′ and convex members 603. In this embodiment, the dry etch process can be a plasma etching process that employs radio frequency energy (RF) to create a plasma of ionized atoms and radicals of reactive gases capable of etching various semiconductors. In this step, the patterned etching stop layer 604′ also serves as an “etching mask”, i.e., the patterned etching stop layer 604′ performs the same function as the patterned photoresist layer 606′. Therefore, the mask is thickened by adding the patterned etching stop layer 604′. When the patterned photoresist layer 606′ is worn in the dry etch process, the patterned etching stop layer 604′ serves as a backup mask. After the dry etch step, the convex members 603 can be formed on the top surface of the substrate 602.

In step F, the patterned photoresist layer 606′ and the patterned etching stop layer 604′ are removed from the top surface of the polygonal convex members 603 so as to expose a top surface of the substrate 602. When the polygons on the nano/micron meter imprint mask 608 are imprint patterns 608a as illustrated in FIG. 6A, the resultant convex members are similar to the convex member 103 as illustrated in FIG. 3. In this embodiment, when the wet etching is not applied to the sidewalls of each convex member 603, an edge number of a top surface of each convex member 603 is equal to a sidewall number of the convex arc-shaped sidewalls of each convex member 603, as in the case of the convex member 103 illustrated in FIG. 3.

When the polygons on the nano/micron meter imprint mask 608 are imprint patterns 608b as illustrated in FIG. 6B, an additional step G of FIG. 5 should be executed to wet etch the sidewalls of each convex member 603 to form convex arc-shaped sidewalls, as in the case of the convex member 103 illustrated in FIG. 2A and FIG. 2B. After the sidewalls of each convex member 603 are wet etched, a sidewall number of the convex arc-shaped sidewalls of each convex member 603 is greater than an edge number of a top surface of each convex member 603, again as in the case of the convex members 103 illustrated in FIG. 2A and FIG. 2B.

According to the above-discussed embodiments, the patterned substrate of a light emitting semiconductor device of this disclosure has the convex members equipped with multiple convex arc-shaped sidewalls to generate more scattering or diffracting light and therefore achieves a higher light extraction rate for the light emitting semiconductor device. Through such a configuration, both top-emitting light power and side-emitting light power are enhanced. Similar advantages are realized with the method for manufacturing a patterned substrate of a light emitting semiconductor device of this disclosure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A patterned substrate of a light emitting semiconductor device comprising a plurality of convex members on a top surface thereof, each convex member having a substantially flat top surface and a plurality of convex arc-shaped sidewalls.

2. The patterned substrate of claim 1, wherein an edge number of a top surface of each convex member is equal to or less than a sidewall number of the convex arc-shaped sidewalls of each convex member.

3. The patterned substrate of claim 1, wherein an edge number of a top surface of each convex member is equal to or less than an edge number of a horizontal cross-section of each convex member, and the horizontal cross-section is parallel with the substantially flat top surface.

4. The patterned substrate of claim 1, wherein the patterned substrate comprises a sapphire substrate or a silicon-based substrate.

5. A light emitting semiconductor device comprising:
a patterned substrate comprising a plurality of convex members on a top thereof, each convex member having a substantially flat top surface and a plurality of convex arc-shaped sidewalls;
a first type semiconductor layer disposed on the patterned substrate;
a light-emitting layer disposed on the first type semiconductor layer; and
a second type semiconductor layer disposed on the light-emitting layer.

6. The light emitting semiconductor device of claim 5, wherein an edge number of a top surface of each convex member is equal to or less than a sidewall number of the convex arc-shaped sidewalls of each convex member.

7. The light emitting semiconductor device of claim 5, wherein an edge number of a top surface of each convex member is equal to or less than an edge number of a horizontal cross-section of each convex member, and the horizontal cross-section is parallel with the substantially flat top surface.

8. The light emitting semiconductor device of claim 5, wherein the patterned substrate comprises a sapphire substrate or a silicon-based substrate.

9. The light emitting semiconductor device of claim 5, wherein the first type semiconductor layer is an n-type semiconductor layer while the second type semiconductor layer is a p-type semiconductor layer, or the first type semiconductor layer is a p-type semiconductor layer while the second type semiconductor layer is an n-type semiconductor layer.

10. A method for manufacturing a patterned substrate of a light emitting semiconductor device comprising:
providing a substrate;
forming an etching stop layer on the substrate;
forming a photoresist layer on the etching stop layer;
using a nano/micron meter imprinting process or a photolithography process to pattern the photoresist layer to form a plurality of polygons;
dry etching the substrate and the etching stop layer using the patterned photoresist layer as a mask so as to form a plurality of polygonal convex members on a top of the substrate;
removing the photoresist layer and the etching stop layer from a top surface of each polygonal convex member; and
wet etching sidewalls of each polygonal convex member so as to form a plurality of convex arc-shaped sidewalls.

11. The method of claim 10, wherein the dry etching is performed using a plasma etching process that employs radio frequency energy to create a plasma of ionized atoms and radicals of reactive gases capable of etching various semiconductors.

12. The method of claim 10, wherein an etchant of the wet etching is a mixed acid solution.

13. The method of claim 10, wherein the etching stop layer is made from a material selected from the group consisting of silicon dioxide and silicon nitride.

14. The method of claim 10, wherein an edge number of a top surface of each convex member is equal to or less than a sidewall number of the convex arc-shaped sidewalls of each convex member.

15. The method of claim 10, wherein an edge number of a top surface of each convex member is equal to or less than an edge number of a horizontal cross-section of each convex member, and the horizontal cross-section is parallel with the substantially flat top surface.

16. The method of claim 10, wherein the patterned substrate comprises a sapphire substrate or a silicon-based substrate.
